(19) United States
(12) Patent Application Publication
(10) Pub. No.: US 2014/0349464 A1
(43) Pub. Date: Nov. 27, 2014

(54) METHOD FOR FORMING DUAL STI STRUCTURE

(71) Applicant: Shanghai Huali Microelectronics Corporation, Shanghai (CN)

(72) Inventors: Yushu YANG, Shanghai (CN); Wei QIN, Shanghai (CN); Haihui HUANG, Shanghai (CN)

(73) Assignee: Shanghai Huali Microelectronics Corporation, Shanghai (CN)

(21) Appl. No.: 14/055,325

(22) Filed: Oct. 16, 2013

(30) Foreign Application Priority Data
May 23, 2013 (CN) 201310195567.4

(51) Int. Cl. H01L 21/762

(52) U.S. Cl. CPC H01L 21/76229
USPC 438/427

(57) ABSTRACT

A method for forming dual shallow trench isolation (STI) structure, which includes a first etching process for forming a deep STI structure in a logic region using a hard mask layer as a mask and a second etching process for forming a shallow STI structure in a pixel region using a photoresist as a mask. Independence between these two etching processes can avoid the prior art problems of double slope profile of the sidewalls of the deep STI structure and a thickness inconsistency of the hard mask layer between on the pixel region and on the logic region.

### CROSS-REFERENCES TO RELATED APPLICATIONS

This application claims the priority of Chinese patent application number 201310195567.4, filed on May 23, 2013, the entire contents of which are incorporated herein by reference.

### TECHNICAL FIELD

The present invention relates generally to methods for forming complementary metal-oxide-semiconductor (CMOS) image sensors, and more particularly, to methods for forming dual depth shallow trench isolation (STI) structures.

### BACKGROUND

Sallow trench isolation (STI) process is an essential process in the manufacture of complementary metal-oxide-semiconductor (CMOS) devices. With the decreasing of the device sizes, the thickness of photoresist allowed to be used is limited, while the STI structure depths are not significantly decreased. This makes the photoresist fail to provide a mask having enough thickness for STI etching. As a result, for technology nodes of 130 nanometers (nm) and beyond, silicon nitride hard masks are widely used for STI etching in the existing CMOS processes.

Currently, the production of CMOS image sensors (CIS) with advanced technology platforms (e.g., sub-65 nm technology node) is popular among chip manufacturers. Such CIS chips typically include both a pixel region and a logic region. This feature differentiates the CIS chips much from conventional logic chips as well as memory chips in manufacturing process. For example, in the crucial STI structure etching process for the existing fabrication of the CIS chips, a dual STI process is generally employed to form STI structures having two different depths respectively in the pixel region and the logic region. The dual STI process mainly includes the steps as follows.

Referring to FIG. 1A, in a first step of the process, a silicon wafer 100 including a pixel region I and a logic region II is provided, and a silicon nitride layer 101, a bottom anti-reflective coating (BARC) layer 102 and a patterned photoresist layer 103 are sequentially formed in this order over the silicon wafer 100.

Referring again to FIG. 1A, in conjunction with FIG. 1B, in a second step of the process, the BARC layer 102, the silicon nitride layer 101 and the silicon wafer 100 are sequentially etched using the patterned photoresist layer 103 as a mask for the etching process to form a shallow STI structure 104a in the pixel region I and a shallow STI structure 104b in the logic region II.

Referring again to FIG. 1B, in conjunction with FIG. 1C, in a third step of the process, the patterned photoresist layer 103 and the BARC layer 102 are removed.

Referring to both FIG. 1D and FIG. 1E, in a fourth step of the process, the pixel region I is again coated with photoresist 103a and the shallow STI structure 104b in the logic region II is further etched using the silicon nitride layer 101 as a hard mask to form a deep STI structure 104c, followed by removing the photoresist 103a, thereby resulting final dual STI structure having two different depths respectively in the pixel region I and the logic region II of the silicon wafer 100.

However, this process suffers from various deficiencies.

One deficiency is that serving as the hard mask for deepening the STI structure 104b by further etching in the fourth step leads to loss of thickness of the silicon nitride layer 101 in the logic region II. Consequently, after the fourth step, the remaining portion of the silicon nitride layer 101 has different thicknesses in the two regions (refer to the thickness difference as indicated by the dashed-line circle 1 in FIG. 1E), and the resulting structure appears therefore like a two-rung ladder overall. This thickness difference may further lead to a height difference between the silicon oxide filled in the STI structures in the pixel and logic regions I, II and the active region of the device being fabricated after a subsequent chemical-mechanical planarization (CMP) process is performed. This may cause certain electrical deficiencies and potential risks for the failure of the device.

Another deficiency is that the deep STI structure in the logic region II is formed by two etching processes using masks formed of different materials (i.e., photoresist used in the first etching process and silicon nitride used in the second etching process) which are deposited in different conditions. This may cause the double slope profile (as indicated by the dashed-line circle 2 in FIG. 1E) of the side rails of the deep STI structure in the logic region II, which will lead to an unfavorable impact on electrical performance of the logic region II.

Therefore, there is a need for a novel method for forming STI structures having two different depths to overcome these deficiencies.

### SUMMARY OF THE INVENTION

Accordingly, an objective of the invention is to provide a method for forming dual STI structures while avoiding the above described prior art problems, i.e., the double slope profile of the sidewalls of the deep STI structure and the thickness inconsistency of the hard mask layer between on the pixel region and on the logic region.

The foregoing objective is attained by a method for forming a dual STI structure in accordance with a first aspect of the present invention. The method includes the following steps in the sequence set forth:

providing a silicon wafer having a first region and a second region;

forming a hard mask layer on the silicon wafer;

forming a first opening in the hard mask layer to expose a portion of the silicon wafer in the second region;

etching the silicon wafer using the hard mask layer as a mask to form a deep STI structure in the second region;

forming an insulating anti-reflection layer filling the deep STI structure and covering the hard mask layer;

coating a photoresist layer on the insulating anti-reflection layer, and forming a second opening in the photoresist layer to expose a portion of the insulating anti-reflection layer in the first region; and

sequentially etching the insulating anti-reflection layer, the hard mask layer and the silicon wafer using the photoresist layer as a mask to form a shallow STI structure in the first region.

In one specific embodiment, the silicon wafer may include a substrate and a dielectric layer on the substrate.

In one specific embodiment, the hard mask layer may be a silicon nitride layer, a silicon oxynitride layer, a multilayer stack of silicon nitride and silicon oxynitride, or a multilayer stack of silicon oxide, silicon nitride and silicon oxide.

In one specific embodiment, the method may further include planarizing the insulating anti-reflection layer after forming the insulating anti-reflection layer and prior to coating the photoresist layer on the insulating anti-reflection layer.

In one specific embodiment, the method may further include removing the photoresist layer and the insulating anti-reflection layer after forming the shallow STI structure.

In one specific embodiment, the method may further include wet cleaning a surface of the silicon wafer after removing the photoresist layer and the insulating anti-reflection layer.

In one specific embodiment, the deep STI structure has a depth of 2800 Å to 3200 Å, and the shallow STI structure has a depth of 1400 Å to 1600 Å.

In one specific embodiment, the first region is a pixel region and the second region is a logic region.

The foregoing objective is also attained by a method for forming a complementary metal-oxide-semiconductor (CMOS) image sensor in accordance with a second aspect of the present invention. The method includes the following steps in the sequence set forth:

providing a silicon wafer having a pixel region and a logic region;

forming a hard mask layer on the silicon wafer;

forming a first opening in the hard mask layer to expose a portion of the silicon wafer in the logic region;

etching the silicon wafer using the hard mask layer as a mask to form a deep STI structure in the logic region;

forming an insulating anti-reflection layer filling the deep STI structure and covering the hard mask layer;

coating a photoresist layer on the insulating anti-reflection layer, and forming a second opening in the photoresist layer to expose a portion of the insulating anti-reflection layer in the pixel region; and

sequentially etching the insulating anti-reflection layer, the hard mask layer and the silicon wafer using the photoresist layer as a mask to form a shallow STI structure in the pixel region.

Advantageously, the method of the present invention forms each of the shallow STI structure in the pixel region and the deep STI structure in the logic region using a totally independent etching process, thus addressing the prior art issues of the double slope profile of the sidewalls of the deep STI structure. Also advantageously, taking advantages of a small depth of the shallow STI structure, the independent etching process for forming the shallow STI structure simply uses photoresist rather than hard mask layer as a mask, thereby preventing local thickness loss of the hard mask layer during the etching process and hence avoiding the prior art problem of a step-like profile of the hard mask layer with a thickness inconsistency between on the pixel region and on the logic region.

### BRIEF DESCRIPTION OF THE DRAWINGS

FIGS. 1A to 1E are cross-sectional views depicting the sequence of process steps of a conventional method to form a dual STI structure.

FIG. 2 depicts a flowchart graphically illustrating a method for forming a dual STI structure in accordance with an embodiment of the present invention.

FIGS. 3A to 3F are cross-sectional views depicting the sequence of process steps of the method for forming a dual STI structure in accordance with an embodiment of the present invention.

### DETAILED DESCRIPTION

The present invention discloses a method for forming a dual STI structure suited to use in the manufacture of complementary metal-oxide-semiconductor (CMOS) image sensors at 65 nm technology node or beyond. The method is capable of forming a dual STI structure by changing the order of the conventional process sequence and modifying the conventional etching processes, i.e., by using independent etching processes to respectively form a deep STI structure in a logic region and a shallow STI structure in a pixel region, while avoiding the prior art problems of double slope profile of the sidewalls of the deep STI structure and a thickness inconsistency of the hard mask layer between on the pixel region and on the logic region.

Other objectives and features of the invention will become apparent from the following detailed description, which, taken in conjunction with the accompanying drawings, discloses a preferred embodiment of the present invention. However, it should be construed that the invention may be practiced other than as specifically described in reference to the preferred embodiment given below.

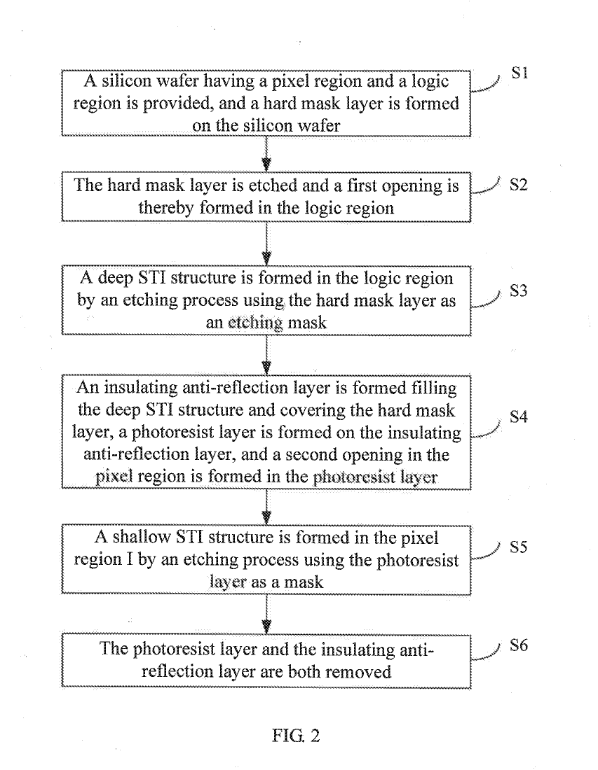

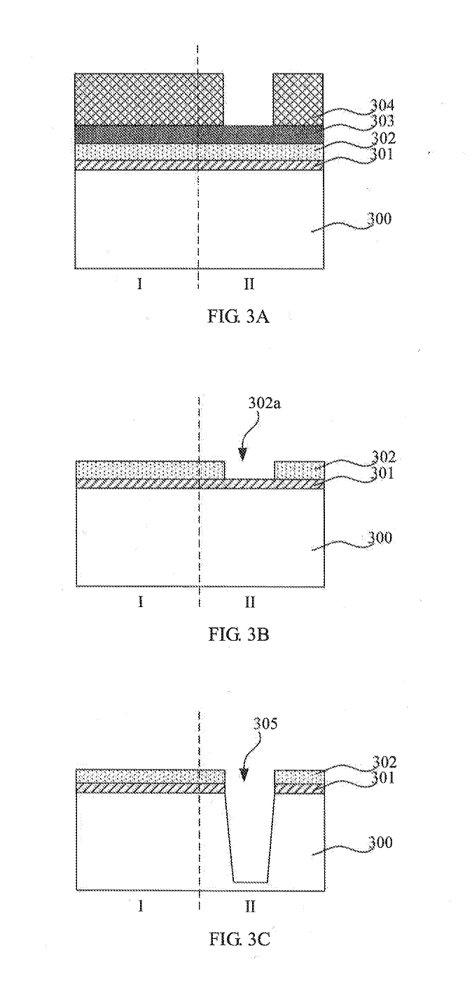

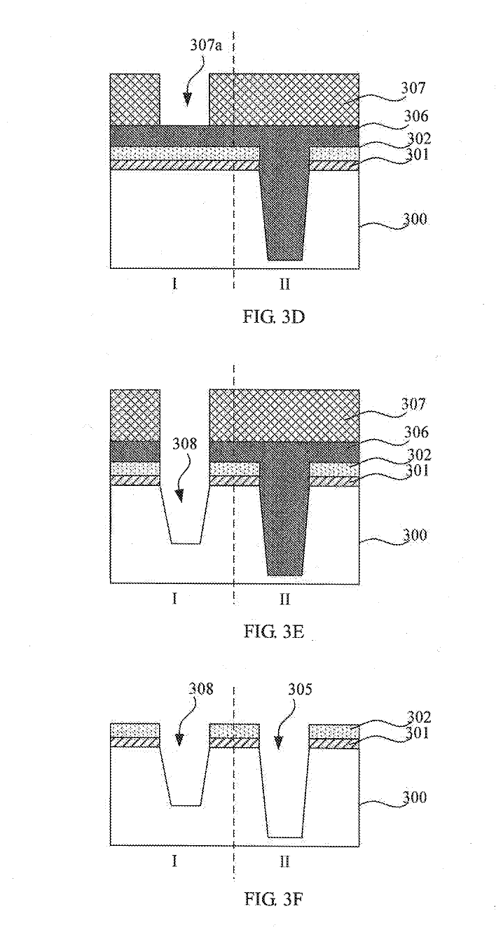

The method of the present invention for forming a dual STI structure will be described in detail with reference to FIG. 2 and FIGS. 3A to 3F.

In a preferred embodiment, the method includes the following steps S1 to S6.

In step S1, a silicon wafer having a pixel region and a logic region is provided, and a hard mask layer is formed on the silicon wafer.

Specifically, referring to FIG. 3A, the silicon wafer may include a substrate 300 and a dielectric layer 301 formed on the substrate 300. The dielectric layer 301 may be a silicon nitride layer. The silicon wafer is defined into a pixel region I and a logic region II. A hard mask layer 302 is formed over the dielectric layer 301. The hard mask layer 302 may be a silicon nitride layer, a silicon oxynitride layer, a multilayer stack of silicon nitride and silicon oxynitride, or a multilayer stack of silicon oxide, silicon nitride and silicon oxide. The hard mask layer 302 may have a thickness of 900 Å and may be formed by chemical vapor deposition (CVD).

In step S2, the hard mask layer is etched and a first opening is thereby formed in the logic region II.

Specifically, referring again to FIG. 3A, in conjunction with FIG. 3B, step S2 may further include the steps of:

sequentially forming a first insulating anti-reflection layer 303 and a first photoresist layer 304 on the hard mask layer 302, wherein in this embodiment, the first insulating anti-reflection layer 303 is a bottom anti-reflective coating (BARC) layer, which may be a monolayer or a multilayer stack with a thickness of 1050 Å, formed of, for example, carbon or spin-on glass (SOG) by means of spin coating or CVD, and wherein the first photoresist layer 304 may be an ArF layer having a thickness of 1950 Å;

defining a location in the logic region II for a deep STI structure to be formed thereat, and forming a deep-STI-structure pattern (i.e., the opening in FIG. 3A) in the first photoresist layer 304 by an exposure and development process, wherein the formed deep-STI-structure pattern is located in the logic region II and exposes a corresponding portion of the underlying first insulating anti-reflection layer 303; and

sequentially etching the first insulating anti-reflection layer 303 and the hard mask layer 302 using the first photoresist layer 304 as a mask, stopping the etching at the dielectric layer 301, and removing the rest of both the first photoresist layer 304 and the first insulating anti-reflection layer 303 using an ashing process, thereby resulting in a structure as shown in FIG. 3B with a first opening 302a in the hard mask layer 302.

In step S3, a deep STI structure is formed in the logic region II by an etching process using the hard mask layer as an etching mask.

Specifically, referring to FIG. 3C, a deep STI structure 305 is formed by etching the silicon wafer (i.e., etching both the dielectric layer 301 and the substrate 300) using the hard mask layer 302 as a mask. The formed deep STI structure 305 may have a depth of 2800 Å to 3200 Å, and in this embodiment, about 3000 Å. The etching process may include methods known to those skilled in the art, such as STI structure etching and STI structure bottom corner rounding, which are not further described herein for the sake of brevity. The etching process in this step generally leads to a thickness loss of the hard mask layer 302 of about 200 Å. Therefore, in order to avoid a discrepancy between the thickness of the hard mask layer 302 after this step and the corresponding design value, an additional sacrificial thickness for compensating for this thickness loss of the hard mask layer 302 should be taken into considerations during the formation of the hard mask layer 302 in step S1.

In step S4, an insulating anti-reflection layer is formed filling the deep STI structure and covering the hard mask layer, a photoresist layer is formed on the insulating anti-reflection layer, and a second opening in the pixel region is formed in the photoresist layer.

Specifically, referring to FIG. 3D, step S4 may further include the steps of:

depositing a second insulating anti-reflection layer 306 by means of, for example, CVD, filling the deep STI structure 305 in the logic region II and covering the hard mask layer 302, and thereafter planarizing the second insulating anti-reflection layer 306, wherein in this embodiment, the second insulating anti-reflection layer 306 is a BARC layer, which may be a monolayer or multilayer stack with a thickness of 1050 Å, formed of, for example, carbon or spin-on glass (SOG) by means of spin coating or CVD, and the planarized second insulating anti-reflection layer 306 may have a thickness of 1050 Å in the pixel region I;

forming a second photoresist layer 307 on the second insulating anti-reflection layer 306, wherein the second photoresist layer 307 may be an ArF layer having a thickness of 2200 Å; and

defining a location in the pixel region I for a shallow STI structure to be formed thereat, and forming a second opening 307a (i.e., a shallow-STI-structure pattern) in the second photoresist layer 307 by an exposure and development process, wherein the formed second opening 307a is located in the pixel region I and exposes a corresponding portion of the underlying second insulating anti-reflection layer 306.

In step S5, a shallow STI structure is formed in the pixel region I by an etching process using the photoresist layer as a mask.

Specifically, referring to FIG. 3E, taking advantage of the fact that photoresist is sufficient to provide a mask because of a minor depth of the intended shallow STI structure, a shallow STI structure 308 is formed in the pixel region I by etching simply using the second photoresist layer 307 as a mask. The etching process may principally include etching the second photoresist layer 306 and the hard mask layer 302, etching the silicon wafer to form the STI structure 308 therein, and rounding the bottom corners of the shallow STI structure 308. The formed shallow STI structure 308 may have a depth of 1400 Å to 1600 Å, and in this embodiment, about 1500 Å. Advantageously, because the second photoresist layer 307 stays on the hard mask layer 302 throughout this step, the hard mask layer 302 is protected and hence has no thickness loss. Therefore, thickness of the hard mask layer 302 remains consistent between on the pixel and on logic regions I, II.

In step S6, the photoresist layer and the insulating anti-reflection layer are both removed.

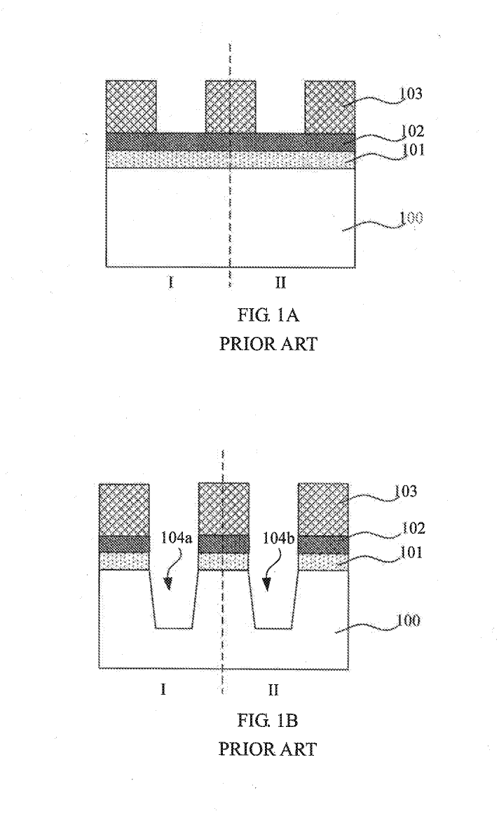

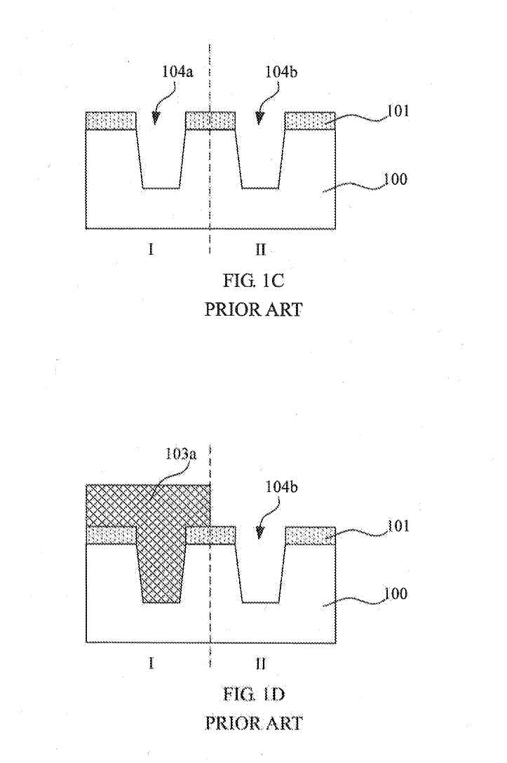

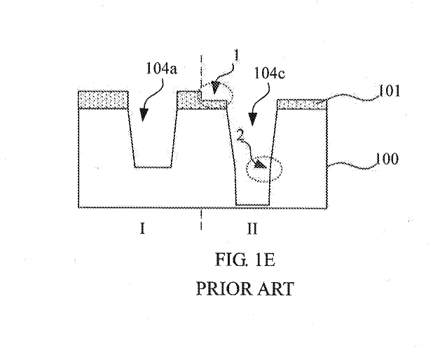

Specifically, referring again to FIG. 3E, in conjunction with FIG. 3F, in step S6, the rest of both the second photoresist layer 307 and the second photoresist layer 306 of the resulting structure from step S5 are removed by an ashing process to expose the deep STI structure 305 and a chemical cleaning process is performed for removing post-etching residues and etching byproducts, thus a final dual STI structure is formed, as shown in FIG. 3F. Differing from the resulting structure (see FIG. 1E) of the prior art method described above, there is no thickness difference in the hard mask layer or double slope profile at the sidewalls of the deep STI structure of the above final structure constructed in accordance with the method of the present invention.

As noted above, the method of the present invention advantageously forms each of the shallow STI structure in the pixel region and the deep STI structure in the logic region using a totally independent etching process, thus addressing the prior art issues of the double slope profile of the sidewalls of the deep STI structure. Also advantageously, taking advantages of a small depth of the shallow STI structure, the independent etching process for forming the shallow STI structure simply uses photoresist rather than hard mask layer as a mask, thereby preventing local thickness loss of the hard mask layer during the etching process and hence avoiding the prior art problem of a step-like profile of the hard mask layer with a thickness inconsistency between on the pixel region and on the logic region. The present invention may be suitably used in the dual STI process for the manufacture of CMOS image sensors (CSI's) at 65 nm technology node or beyond, particularly 40/45 nm or beyond.

It is apparent that those skilled in the art can make various modifications and variations to the present invention without departing from the scope of the invention. Accordingly, it is intended that the present invention embraces all such modifications and variations as fall within the scope of the appended claims and equivalents thereof.

What is claimed is:

1. A method for forming dual STI structure, comprising the following steps in the sequence set forth:
providing a silicon wafer having a first region and a second region;
forming a hard mask layer on the silicon wafer;
forming a first opening in the hard mask layer to expose a portion of the silicon wafer in the second region;
etching the silicon wafer using the hard mask layer as a mask to form a deep STI structure in the second region;
forming an insulating anti-reflection layer filling the deep STI structure and covering the hard mask layer;
coating a photoresist layer on the insulating anti-reflection layer, and forming a second opening in the photoresist layer to expose a portion of the insulating anti-reflection layer in the first region; and
sequentially etching the insulating anti-reflection layer, the hard mask layer and the silicon wafer using the photoresist layer as a mask to form a shallow STI structure in the first region.

2. The method of claim 1, wherein the silicon wafer includes a substrate and a dielectric layer on the substrate.

3. The method of claim 1, wherein the hard mask layer is a silicon nitride layer, a silicon oxynitride layer, a multilayer stack of silicon nitride and silicon oxynitride, or a multilayer stack of silicon oxide, silicon nitride and silicon oxide.

4. The method of claim 1, further comprising planarizing the insulating anti-reflection layer after forming the insulating anti-reflection layer and prior to coating the photoresist layer on the insulating anti-reflection layer.

5. The method of claim 1, further comprising removing the photoresist layer and the insulating anti-reflection layer after forming the shallow STI structure.

6. The method of claim 5, further comprising wet cleaning a surface of the silicon wafer after removing the photoresist layer and the insulating anti-reflection layer.

7. The method of claim 1, wherein the deep STI structure has a depth of 2800 Å to 3200 Å, and the shallow STI structure has a depth of 1400 Å to 1600 Å.

8. The method of claim 1, wherein the first region is a pixel region and the second region is a logic region.

9. A method of forming a complementary metal-oxide-semiconductor (CMOS) image sensor, comprising the following steps in the sequence set forth:
providing a silicon wafer having a pixel region and a logic region;
forming a hard mask layer on the silicon wafer;
forming a first opening in the hard mask layer to expose a portion of the silicon wafer in the logic region;
etching the silicon wafer using the hard mask layer as a mask to form a deep STT structure in the logic region;
forming an insulating anti-reflection layer filling the deep STI structure and covering the hard mask layer;
coating a photoresist layer on the insulating anti-reflection layer, and forming a second opening in the photoresist layer to expose a portion of the insulating anti-reflection layer in the pixel region; and
sequentially etching the insulating anti-reflection layer, the hard mask layer and the silicon wafer using the photoresist layer as a mask to form a shallow STI structure in the pixel region.

10. The method of claim 9, wherein the silicon wafer includes a substrate and a dielectric layer on the substrate.

11. The method of claim 9, wherein the hard mask layer is a silicon nitride layer, a silicon oxynitride layer, a multilayer stack of silicon nitride and silicon oxynitride, or a multilayer stack of silicon oxide, silicon nitride and silicon oxide.

12. The method of claim 9, further comprising planarizing the insulating anti-reflection layer after forming the insulating anti-reflection layer and prior to coating the photoresist layer on the insulating anti-reflection layer.

13. The method of claim 9, further comprising removing the photoresist layer and the insulating anti-reflection layer after forming the shallow STI structure.

14. The method of claim 13, further comprising wet cleaning a surface of the silicon wafer after removing the photoresist layer and the insulating anti-reflection layer.

15. The method of claim 9, wherein the deep STI structure has a depth of 2800 Å to 3200 Å, and the shallow STI structure has a depth of 1400 Å to 1600 Å.

16. The method of claim 9, wherein the CMOS image sensor has a critical dimension of smaller than 65 nanometers.
